(19) United States
(12) Patent Application Publication
(10) Pub. No.: US 2005/0066901 A1
(43) Pub. Date: Mar. 31, 2005

(54) Vacuum deposition method and vacuum deposition device

(75) Inventor: Yuji Isoda, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 10/952,854

(22) Filed: Sep. 30, 2004

(30) Foreign Application Priority Data
Sep. 30, 2003 (JP) 2003-342208
Sep. 17, 2004 (JP) 2004-271600

(51) Int. Cl. C23C 16/00

(52) U.S. Cl. 118/726; 427/248.1

(57) ABSTRACT

The vacuum deposition device includes a vacuum deposition chamber, a vacuum evacuator for evacuating an inside of the chamber, at least one first evaporator which evaporates a first film forming, at least one second evaporator which evaporates a second film forming material. One of the first and second evaporators which is closer to the substrate is spaced apart from the substrate in a vertical direction by 100 to 300 mm. The substrate, the first evaporator and the second evaporator are installed at positions, which satisfy a condition of an expression (1): 0.3≦L₁/L₂≦50. L₁ is a distance in a vertical direction from a horizontal plane of a first or second evaporation port of the first or second evaporator to a surface of the substrate, and L₂ is the shortest distance between the first evaporation port and the second evaporation port.

### BACKGROUND OF THE INVENTION

The present invention relates to a vacuum deposition method and a vacuum deposition device and more specifically to a vacuum deposition method and a vacuum deposition device capable of forming a high-quality deposited film even when deposition is carried out under medium vacuum.

There are known a class of phosphors which accumulate a portion of applied radiations (e.g., X-rays, α-rays, β-rays, γ-rays, electron beam, and ultraviolet radiation) and which, upon stimulation by exciting light such as visible light, give off a burst of light emission in proportion to the accumulated energy. Such phosphors called “stimulable phosphors” are employed in medical and various other applications.

Known as an exemplary application is a radiation image information recording and reproducing system which employs a sheet (phosphor sheet) having a layer (to be referred to as “phosphor film” hereinafter) containing this stimulable phosphor. This phosphor sheet is called “radiation image converting panel (IP)” and is referred to as “phosphor sheet” in the following description. This system has already been commercialized by various companies including Fuji Photo Film Co., Ltd. which has marketed FCR (Fuji Computed Radiography).

In this system, radiation image information about a subject such as the human body is recorded on the phosphor sheet (more specifically, phosphor film). After that, the phosphor sheet is scanned two-dimensionally with exciting light such as laser light to produce stimulated emission. This stimulated emission is read photoelectrically to yield an image signal and an image reproduced on the basis of the image signal is output as a visible image, on a recording material such as a photographic material or on a display device such as CRT. The phosphor sheet which has been read is used repeatedly by erasing the residual image.

The above phosphor sheet is typically produced by: preparing a paint having the particles of a stimulable phosphor dispersed in a solvent containing a binder, etc.; applying the paint to a support in a sheet form that is made of glass, resin, or the like; and drying the applied coating to form a phosphor film.

Phosphor sheets are also known, which are made by forming a phosphor film on a support through methods of physical vapor deposition (vapor-phase film formation) such as vacuum deposition and sputtering (see, for example, JP 2003-172799 A).

The phosphor film formed on the support by evaporation has excellent characteristics. First, it contains less impurities since it is formed under vacuum; in addition, it is substantially free of any substances other than the stimulable phosphor, as exemplified by the binder, so it has high uniformity in performance and still assures very high luminous efficiency. This vacuum deposition method forms a phosphor film on the surface of a substrate by evaporating one or more film forming material with one ore more evaporators in an evaporating unit within a vacuum container.

To obtain excellent photostimulated luminescence characteristics, it is preferred that phosphor crystals should be grown to form a column (columnar crystal) having a sufficient height and good shape. To this end, it is known to be preferable that deposition be carried out at a lower degree of vacuum than usual. For instance, there is proposed a method of separating out needle-like crystals of a fluorescent substance by carrying out deposition at a relatively low degree of vacuum, i.e., 1 to 10 Pa (for example, US2001/0010831A1).

### SUMMARY OF THE INVENTION

When vacuum deposition is carried out by using a vacuum deposition device, a plurality of different film forming materials may be used to carry out vacuum deposition. For example, there is known a method of forming a phosphor film of the above phosphor sheet by vacuum deposition using CsBr as a main material and EuBr₂ as an activator. In the manufacture of a phosphor sheet, an extremely small amount of an activator is used as compared with a phosphor, and the control of the components of the phosphor film is important. Therefore, it is preferred to form a film on the substrate by generating vapor of the phosphor and that of the activator separately and then fully mixing them together. To form a phosphor film having a uniform composition, two evaporators in an evaporating unit for the phosphor film forming material and the activator film forming material are preferably arranged close to each other. That is, as the two evaporators are closer to each other, a higher-quality phosphor film containing the activator dispersed therein uniformly can be formed. In addition, an area for mixing together the two vapors can be made wider, which makes it possible to improve the use efficiency of the materials.

On the other hand, when an evaporator for evaporating the main material and an evaporator for evaporating the activator are close to each other, heat generated from one evaporator interfere with heat from the other evaporator, whereby it may be difficult to control the temperature of each evaporator and the formed phosphor film may be deteriorated. Therefore, when multi-source vapor deposition is carried out by using a plurality of evaporators under so-called “medium vacuum” where excellent crystal growth can be expected, there must be the arrangement of evaporators most suitable for multi-source deposition.

However, including JP 2003-172799 and US 2001/0010831A1, no documents disclose the arrangement of evaporators when multi-source deposition is carried out under medium vacuum or suggest that this multi-source deposition involves the above problem.

The present invention has been made in view of the above situation and an object of the present invention is to provide a vacuum deposition method by which a deposition layer having uniform film thickness, composition and film forming material concentration, and excellent crystallinity can be formed.

Another object of the present invention is to provide a vacuum deposition device for implementing the vacuum deposition method.

In order to attain the above-mentioned object, a first aspect of the present invention provides a vacuum deposition method, comprising the steps of: evaporating film forming materials from an evaporating unit installed in a vacuum deposition chamber; and depositing the evaporated film forming materials on a surface of a substrate located above the evaporating unit, wherein the evaporating unit includes at least one first evaporator for evaporating a first film forming material and at least one second evaporator for evaporating a second film forming material; and wherein the first and second film forming materials are deposited on the surface of the substrate at a pressure of 0.05 to 10 Pa by installing the substrate, the first evaporator and the second evaporator at positions which satisfy a condition of an expression (1):
0.3≦L₁/L₂≦50 (1)
wherein L₁ is a distance in a vertical direction from a horizontal plane of an evaporation port of the first or second evaporator to the surface of the substrate, and L₂ is the shortest distance between the evaporation port of the first evaporator and the evaporation port of the second evaporator. L₁/L₂ preferably satisfies 1≦L₁/L₂≦50 and more preferably 1≦L₁/L₂≦20.

It is preferable that the first and second film forming materials be deposited on the substrate while the substrate is turned at a number of revolution R₁ which satisfies 1≦R₁≦20 (rpm) relative to the first and second evaporators.

It is preferable that the first and second film forming materials be deposited on the substrate by linearly transporting the substrate.

It is preferable that the substrate be transported at a transport speed of 1 to 1000 mm/sec.

It is preferable that first evaporators and second evaporators be used in the evaporating unit, and a line of the first evaporators and a line of the second evaporators be arranged parallel to each other in a direction parallel to the substrate and perpendicular to a direction in which the substrate is transported, whereby the first and second film forming materials are deposited on the substrate.

It is preferable that the first film forming material comprise CsBr and the second film forming material comprise EuBr₂.

In order to attain the above-mentioned object, a second aspect of the present invention provides a vacuum deposition device, comprising: a vacuum deposition chamber; vacuum evacuation means for evacuating inside of the vacuum deposition chamber; at least one first evaporator which is installed in the vacuum deposition chamber and which evaporates a first film forming material from a first evaporation port; at least one second evaporator which is installed in the vacuum deposition chamber and which evaporates a second film forming material from a second evaporation port; and a holding unit for holding a substrate on which the first film forming material and the second film forming material are deposited, the holding unit being provided above the first and second evaporators, wherein one of the first and second evaporators which is closer to the substrate is spaced apart from the substrate in a vertical direction by 100 to 300 mm; and wherein the substrate, the first evaporator and the second evaporator are installed at positions which satisfy a condition of an expression (1):
0.3≦L₁/L₂≦50 (1)
wherein L₁ is a distance in a vertical direction from a horizontal plane of the first or second evaporation port of the first or second evaporator to a surface of the substrate, and L₂ is the shortest distance between the first evaporation port of the first evaporator and the second evaporation port of the second evaporator. L₁/L₂ preferably satisfies 1≦L₁/L₂≦50 and more preferably 1≦L₁/L₂≦20.

It is preferable that the holding unit hold the substrate in such a manner that the substrate turns on a plane opposed to a wall of the vacuum deposition chamber in which the first and second evaporators are installed.

It is preferable that the vacuum deposition device further include linear transport means for linearly transporting the substrate by linearly moving the holding unit.

It is preferable that the first evaporators and second evaporators be used in the vacuum deposition chamber and a line of the first evaporators and a line of the second evaporators are arranged parallel to each other in a direction parallel to the substrate and perpendicular to a direction in which the substrate is transported.

It is preferable that the first film forming material comprise CsBr and the second film forming material comprise EuBr₂.

According to the vacuum deposition method of the present invention, the film forming materials are deposited on the substrate by arranging the evaporators and the substrate in the vacuum deposition chamber so that L₁ and L₂ satisfy the following expression (1):
0.3≦L₁/L₂≦50 (1)
wherein L₁ is the distance in the vertical direction from the horizontal plane of the evaporation port of the first or second evaporator to the surface of the substrate, and L₂ is the distance between the evaporation port of the first evaporator and the evaporation port of the second evaporator. Therefore, a deposition layer having uniform film thickness, composition and film forming material concentration, and excellent crystallinity can be formed on the substrate.

Further, in the vacuum deposition device of the present invention, the evaporators and the substrate are arranged so that the distance L₁ in the vertical direction from the horizontal plane of the evaporation port of the first or second evaporator to the surface of the substrate, and the distance L₂ between the evaporation port of the first evaporator and the evaporation port of the second evaporator satisfy the expression (1). Therefore, the vacuum deposition method of the present invention can be implemented to allow a deposition layer having uniform film thickness, composition and film forming material concentration, and excellent crystallinity to be formed on the substrate.

This application claims priority on Japanese patent applications No.2003-342208 and No.2004-271600, the entire contents of which are hereby incorporated by reference. In addition, the entire contents of literatures cited in this specification are incorporated by reference.

### BRIEF DESCRIPTION OF THE DRAWINGS

In the accompanying drawings:

FIG. 1 is a schematic side view of the inside of a vacuum deposition device, showing a schematic structure of the vacuum deposition device according to an embodiment of the present invention;

FIG. 2 is a schematic longitudinal sectional view showing a position relationship among a turntable, a substrate and evaporators of the device according to the first embodiment of the present invention;

FIG. 3A is a schematic plan view showing a position relationship between a first evaporator and a second evaporator according to the first embodiment of the present invention;

FIG. 3B is a schematic side view showing a position relationship between the evaporators and the substrate according to the first embodiment of the present invention;

FIG. 4 is a schematic plan view showing the position relationship between the first evaporator and the second evaporator according to the first embodiment of the present invention;

FIG. 5 is a plan view showing the arrangement of the first evaporators and the second evaporators according to Modification 1 of the present invention;

FIG. 6 is a plan view showing the arrangement of the first evaporators and the second evaporators according to Modification 2 of the present invention;

FIG. 7 is a plan view showing the arrangement of the first evaporators and the second evaporators according to Modification 3 of the present invention;

FIG. 8 is a side view showing a schematic constitution of a vacuum deposition device which linearly transports a substrate;

FIG. 9A and 9B are a plan view and a side view showing the arrangement of evaporators when the substrate is linearly transported; and

FIG. 10 shows layouts of the evaporators mounted in the vacuum deposition device which linearly transports the substrate.

### DETAILED DESCRIPTION OF THE PREFERRED EMBODIMENTS

The vacuum deposition method and device according to the present invention will be described below in detail with reference to the preferred embodiments shown in the accompanying drawings.

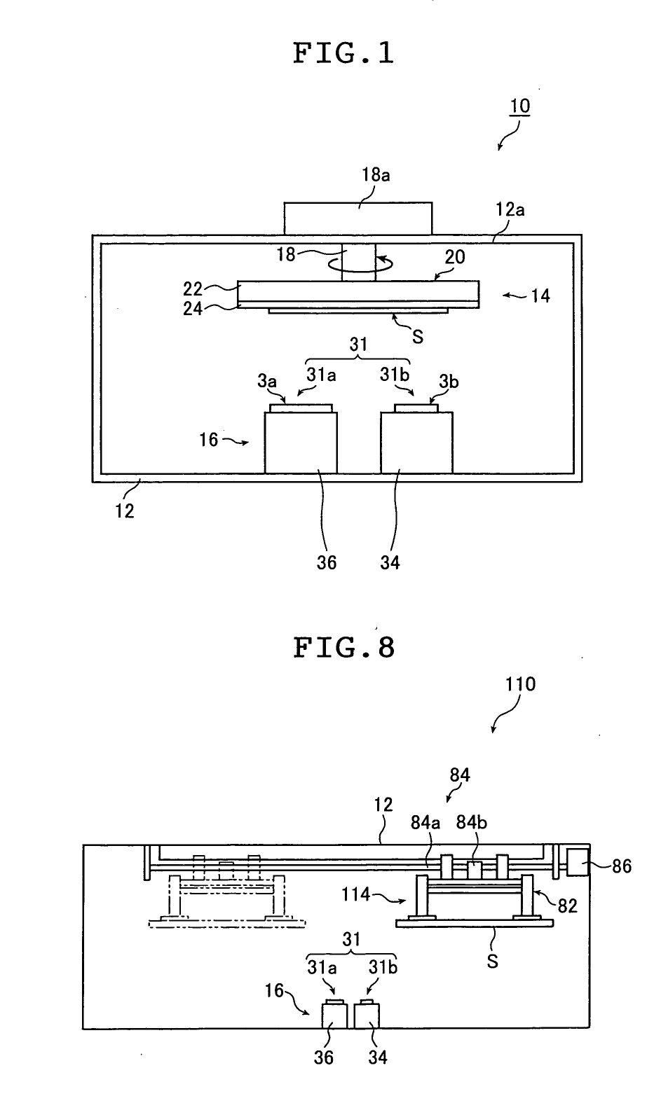

FIG. 1 is a schematic side view of the inside of a vacuum deposition device 10 (to be simply referred to as “device” hereinafter) according to an embodiment of the present invention, showing a schematic structure of the vacuum deposition device 10. The device 10 according to this embodiment is used to manufacture a phosphor sheet by forming a stimulable phosphor film on the surface of a sheet-like glass substrate (to be simply referred to as “substrate” hereinafter) S as a substrate by two-source vapor deposition.

The device 10 according to this embodiment is a so-called substrate rotation type vacuum deposition device which basically includes a vacuum chamber 12 as a vacuum deposition chamber, a substrate holding and rotating mechanism 14 as a holding unit (holding means), and a heating evaporating section 16 as an evaporating unit. As will be described hereinafter, the device 10 according to this embodiment may include a thermal shielding plate (not shown) for blocking out radiation heat from the heating evaporating section 16 toward the substrate in the vacuum chamber 12.

In addition to the above components, the device 10 according to this embodiment is a so-called substrate rotation type vacuum deposition device which basically includes a vacuum chamber 12 as a vacuum deposition chamber, a substrate holding and rotating mechanism 14 as a holding unit (holding means), and a heating evaporating section 16 as an evaporating unit. As will be described hereinafter, the device 10 according to this embodiment may include a thermal shielding plate (not shown) for blocking out radiation heat from the heating evaporating section 16 toward the substrate in the vacuum chamber 12.

The device 10 according to this embodiment carries out two-source vacuum deposition of cesium bromide (CsBr) and europium bromide (EuBr₂) as film forming materials to form a phosphor film of CsBr:Eu as a stimulable phosphor on the glass substrate S to manufacture a phosphor sheet.

The stimulable phosphor is not limited to the above CsBr:Eu and various materials can be used. A stimulable phosphor which gives off light having a wavelength of 300 nm to 500 nm upon stimulation by excitation light having a wavelength of 400 to 900 nm is preferably used.

Various materials can be used as the stimulable phosphor constituting the phosphor film. Preferred examples of the stimulable phosphor are given below.

Stimulable phosphors disclosed in U.S. Pat. No. 3,859,527 are “SrS:Ce, Sm”, “SrS:Eu, Sm”, “ThO₂:Er”, and “La₂O₂S:Eu, Sm”.

JP 55-12142 A discloses “ZnS:Cu, Pb”, “BaO.xAl₂O₃:Eu (0.8≦x≦10)”, and stimulable phosphors represented by the general formula “M^{II}O.xSiO₂:A”. In this formula, M^{II} is at least one element selected from the group consisting of Mg, Ca, Sr, Zn, Cd, and Ba, A is at least one element selected from the group consisting of Ce, Tb, Eu, Tm, Pb, Tl, Bi, and Mn, and 0.5≦x≦2.5.

Stimulable phosphors represented by the general formula “LnOX:xA” are disclosed by JP 55-12144 A. In this formula, Ln is at least one element selected from the group consisting of La, Y, Gd, and Lu, X is at least one element selected from Cl and Br, A is at least one element selected from Ce and Tb, and 0≦x≦0.1.

Stimulable phosphors represented by the general formula “(Ba₁₋ₓ, M²⁺ₓ)FX:yA” are disclosed by JP 55-12145 A. In this formula, M²⁺ is at least one element selected from the group consisting of Mg, Ca, Sr, Zn, and Cd, X is at least one element selected from Cl, Br, and I, A is at least one element selected from Eu, Tb, Ce, Tm, Dy, Pr, Ho, Nd, Yb, and Er, 0≦x≦0.6, and 0≦y≦0.2.

JP 57-14825 A discloses the following stimulable phosphors. That is, the stimulable phosphors are represented by the general formula “xM₃(PO₄)₂.NX₂:yA” or “M₃(PO₄)₂.yA”. In this formula, M and N are each at least one element selected from the group consisting of Mg, Ca, Sr, Ba, Zn, and Cd, X is at least one element selected from F, Cl, Br, and I, A is at least one element selected from Eu, Tb, Ce, Tm, Dy, Pr, Ho, Nd, Yb, Er, Sb, Tl, Mn, and Sn, 0≦x≦6, and 0≦y≦1.

Stimulable phosphors are represented by the general formula “nReX₃.mAX′₂:xEu” or “nReX₃.mAX′₂:xEu, ySm”. In this formula, Re is at least one element selected from the group consisting of La, Gd, Y, and Lu, A is at least one element selected from Ba, Sr, and Ca, X and X′ are each at least one element selected from F, Cl, and Br, 1×10⁻⁴<x<3×10⁻¹, 1×10⁻⁴<y<1×10⁻¹, and 1×10⁻³<n/m<7×10⁻¹.

Alkali halide-based stimulable phosphors are represented by the general formula “M^{I}X.aM^{II}X′₂.bM^{III}X″₃: cA”. In this formula, M^{I} represents at least one element selected from the group consisting of Li, Na, K, Rb, and Cs. M^{II} represents at least one divalent metal selected from the group consisting of Be, Mg, Ca, Sr, Ba, Zn, Cd, Cu, and Ni. M^{III} represents at least one trivalent metal selected from the group consisting of Sc, Y, La, Ce, Pr, Nd, Pm, Sm, Eu, Gd, Tb, Dy, Ho, Er, Tm, Yb, Lu, Al, Ga, and In. X, X′, and X″ each represent at least one element selected from the group consisting of F, Cl, Br, and I. A represents at least one element selected from the group consisting of Eu, Tb, Ce, Tm, Dy, Pr, Ho, Nd, Yb, Er, Gd, Lu, Sm, Y, Tl, Na, Ag, Cu, Bi, and Mg, 0≦a≦0.5, 0≦b<0.5, and 0≦c<0.2.

Stimulable phosphors are represented by the general formula “(Ba₁₋ₓM^{II}ₓ)F₂.aBaX₂:yEu, zA” disclosed by JP 56-116777 A. In this formula, M^{II} is at least one element selected from the group consisting of Be, Mg, Ca, Sr, Zn, and Cd, X is at least one element selected from Ci, Br, and I, A is at least one element selected from Zr and Sc, 0.5≦a≦1.25, 0≦x≦1, 1×10⁻⁶≦y≦2×10⁻¹ and 0≦z≦1×10⁻².

Stimulable phosphors represented by the general formula “M^{III}OX:xCe” are disclosed by JP 58-69281 A. In this formula, M^{III} is at least one trivalent metal selected from the group consisting of Pr, Nd, Pm, Sm, Eu, Tb, Dy, Ho, Er, Tm, Yb, and Bi, X is at least one element selected from Cl and Br, and 0≦x≦0.1.

Stimulable phosphors represented by the general formula “Ba₁₋ₓMₐLₐFX:yEu²⁺” are disclosed by JP 58-206678 A. In this formula, M is at least one element selected from the group consisting of Li, Na, K, Rb, and Cs, L is at least one trivalent metal selected from the group consisting of Sc, Y, La, Ce, Pr, Nd, Pm, Sm, Gd, Tb, Dy, Ho, Er, Tm, Yb, Lu, Al, Ga, In, and Tl, X is at least one element selected from Cl, Br, and I, 1×10⁻²≦x≦0.5, 0≦y≦0.1, and a is x/2.

Stimulable phosphors represented by the general formula “M^{II}FX.aM^{I}X′.bM′^{II}X″₂.cM^{III}X₃.xA:yEu²⁺” are disclosed by JP 59-75200 A. In this formula, M^{II} is at least one element selected from the group consisting of Ba, Sr, and Ca, M^{I} is at least one element selected from Li, Na, K, Rb, and Cs, M′^{II} is at least one divalent metal selected from Be and Mg, M^{III} is at least one trivalent metal selected from the group consisting of Al, Ga, In, and Tl, A is a metal oxide, X, X′, and X″ are each one element selected from the group consisting of F, Cl, Br, and I, 0≦a≦2, 0≦b≦1×10⁻², 0≦c≦1×10⁻², and a+b+c≧10⁻⁶, 0<x≦0.5, and 0<y≦0.2.

Alkali halide-based stimulable phosphors disclosed by JP 57-148285 A are preferred because they have excellent photostimulated luminescence characteristics and the effect of the present invention is advantageously obtained. Alkali halide-based stimulable phosphors in which M^{I} contains at least Cs, X contains at least Br, and A is Eu or Bi are more preferred, and stimulable phosphors represented by the general formula “CsBr:Eu” are particularly preferred.

In the present invention, a phosphor film made of the above stimulable phosphor is formed by vacuum deposition.

In particular, multi-source vacuum deposition for evaporating a phosphor component material and an activator component material by heating them separately is carried out. For example, to form the above CsBr:Eu phosphor film, multi-source vacuum deposition for evaporating cesium bromide (CsBr) as the phosphor component material and europium bromide (EuBr₂) as the activator component material by heating them separately is carried out. Heating methods for vacuum deposition are not particularly limited but resistance heating is preferred to carry out vapor deposition under so-called medium vacuum as in the present invention. Further, to carry out multi-source vacuum deposition, the same heating means (for example, electron beam heating) may be used to evaporate all the materials, or electron beam heating may be used to evaporate the phosphor component material and resistance heating may be used to evaporate a trace amount of the activator component material.

In the device 10 according to this embodiment, the ultimate degree of vacuum in the vacuum chamber 12 is about 1×10−5 Pa to 1×10⁻² Pa. The pressure of moisture in the atmosphere of the vacuum deposition device 10 is preferably set at 7.0×10⁻³ Pa or less by using a diffusion pump (or turbo-molecular pump). An inert gas such as Ar gas, Ne gas, or N₂ gas is introduced under evacuation to control the degree of vacuum to about 0.05 to 10 Pa, preferably about 0.5 to 1.5 Pa.

The deposition condition (so-called “medium vacuum condition”) that the degree of vacuum is set at about 0.05 to 10 Pa, preferably about 0.5 to 1.5 Pa by introducing an inert gas such as Ar gas, Ne gas, or N₂ gas while the above condition is maintained can provide a good shape to the column of the formed stimulable phosphor (columnar structure). As a result, the X-ray characteristics can be improved. In particular, image nonuniformity (structure) of the formed stimulable phosphor can be alleviated.

The term “image nonuniformity (structure)” means (A) the nonuniformity of an X-ray image when an X-ray photo is taken using a phosphor sheet (deposition IP/radiation image converting panel) manufactured by forming a phosphor film on the surface of a substrate by vacuum deposition and (B) the columnarity, that is, the perfection of the columnar structure of a phosphor crystal constituting a phosphor film formed on the surface of the substrate of a phosphor sheet (specifically, the height of the aspect ratio of a columnar crystal, space uniformity, the existence of hillock).

As will be described hereinafter, out of those, the image nonuniformity is particularly important in the vacuum deposition device according to this embodiment. The image nonuniformity (A) is mainly caused by nonuniformity in the thickness of the phosphor film formed on the surface of the substrate of the phosphor sheet and a phenomenon that even when an X-ray having uniform intensity is applied to the entire surface of the phosphor sheet, the obtained X-ray image has a portion which appears to be light and a portion which appears to be dark. More specifically, this image nonuniformity is caused by three factors: (1) nonuniformity in the concentration of Eu; (2) nonuniformity in the thickness of the phosphor film formed on the surface of the substrate; and (3) columnarity. The thick portion of the phosphor film has a large amount of the absorbed X-ray and appears to be light on the X-ray image and the thin portion of the phosphor film has a small amount of the absorbed X-ray and appears to be dark on the X-ray image. As an index for judging this image nonuniformity, there is a method of comparing PSL (photostimulated luminescence) values of portions of a phosphor sheet by measuring these.

Stated more specifically, it is judged based on “PSL uniformity (after the correction of film thickness)” which is shown in Table 1 to be described hereinafter and “film thickness variations” and “columnarity” which are shown in Table 2 to be described hereinafter. The image uniformity can be improved by forming a film under the above conditions.

The perfection of the columnar structure of the phosphor crystal is evaluated based on three factors as indices: (a) high aspect ratio of each crystal (high aspect ratio); (b) uniform spacing between adjacent columnar crystals (uniform spacing); and (c) observation of no hillock because phosphor crystals constituting the phosphor film grow in a direction substantially perpendicular to the surface of the substrate (absence of hillock). The term “hillock” as used herein refers to the state in which the crystal grew in the inclined direction with respect to the surface of the substrate.

The phosphor film may be heated at 50 to 400° C. by heating the substrate during film formation. Further, the thickness of the phosphor film to be formed is not particularly limited but preferably 10 to 1,000 μm, particularly preferably 20 to 800 μm.

The vacuum chamber 12 is a known vacuum chamber (bell jar, vacuum tank) which is made of iron, stainless steel, or aluminum and used in a vacuum deposition device. In the illustrated embodiment, the substrate holding and rotating mechanism 14 and the heating evaporating section 16 are installed in the upper and lower parts of the vacuum chamber 12, respectively.

As described above, the vacuum chamber 12 is connected to a vacuum pump (not shown) as evacuation means. The vacuum pump is not particularly limited and various vacuum pumps used in a vacuum deposition device may be used if they can achieve a required ultimate degree of vacuum. For example, an oil diffusion pump, cryopump, or turbo-molecular pump may be used, and a cryocoil or the like may be used in combination with the vacuum pump.

The substrate holding and rotating mechanism 14 turns while holding the substrate S and includes a rotary shaft 18 to be engaged with a rotation drive source (motor) 18a and a turntable 20. The turntable 20 is a disk member consisting of a body 22 on the upper side in FIG. 1 and a sheathed heater 24 on the lower side in FIG. 1 (on the heating evaporating section 16 side), and the rotary shaft 18 engaged with the above motor 18a is fixed to the center of the disk. The turntable 20 holds the substrate S on its undersurface (undersurface of the sheathed heater 24) on the heating evaporating section 16 side, that is, the evaporation position of the film forming materials and is turned at a predetermined speed by the rotary shaft 18. The sheathed heater 24 heats the substrate S on which a film is formed from its rear side (side opposite to the film forming side).

The substrate S which can be used herein is not particularly limited and various substrates used in phosphor panels may be used. Examples of the substrate S include: plastic films such as a cellulose acetate film, polyester film, polyethylene terephthalate film, polyamide film, polyimide film, triacetate film, and polycarbonate film; glass plates made of quartz glass, non-alkali glass, soda glass, heat resistant glass (Pyrex™, etc.), and the like; metal sheets such as an aluminum sheet, iron sheet, copper sheet and chromium sheet; and metal sheets having a metal oxide coating layer.

The heating evaporating section 16 is installed in the lower part of the vacuum chamber 12 in FIG. 1. As described above, the illustrated device 10 uses cesium bromide (CsBr) as a first film forming material and europium bromide (EuBr₂) as a second film forming material to carry out two-source vacuum deposition in which these two materials are heated separately to be evaporated. Therefore, the heating evaporating section 16 has two kinds of evaporators: a cesium evaporator (to be referred to as “Cs evaporator” hereinafter) 31a as a first evaporator and a europium evaporator (to be referred to as “Eu evaporator” hereinafter) 31b as a second evaporator.

The Cs evaporator 31a has the function of evaporating cesium bromide (main crystal material) in an evaporation position (crucible) by resistance heating with a resistance heater 36. The Eu evaporator 31b has the function of evaporating europium bromide (activator material) in an evaporating position (crucible) by resistance heating with a resistance heater 34.

In this embodiment, the means for evaporating cesium bromide and the means for evaporating europium bromide are not particularly limited and any heating evaporating means may be used if it can provide a sufficiently high film forming speed for a phosphor film essentially composed of a phosphor and having a thickness of more than 200 μm. Each evaporation position is provided with material feed means (not shown) for feeding each material.

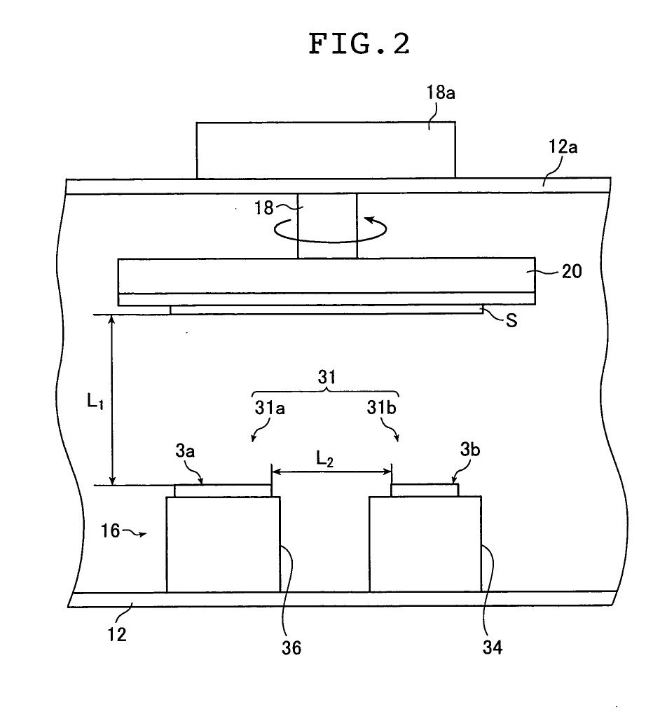

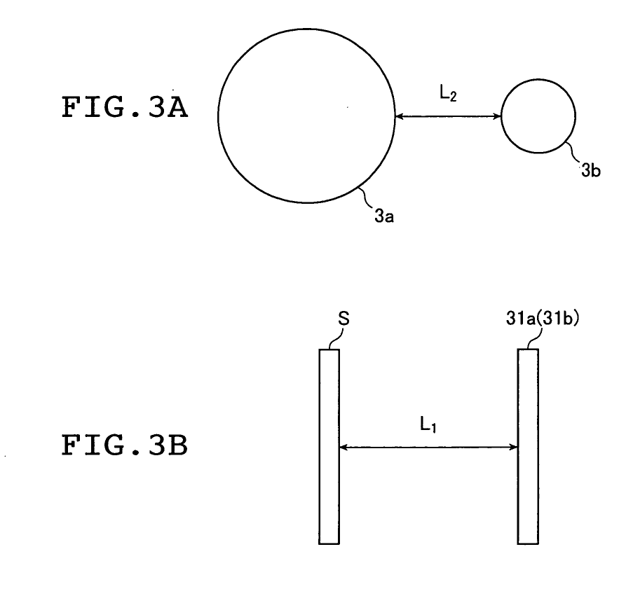

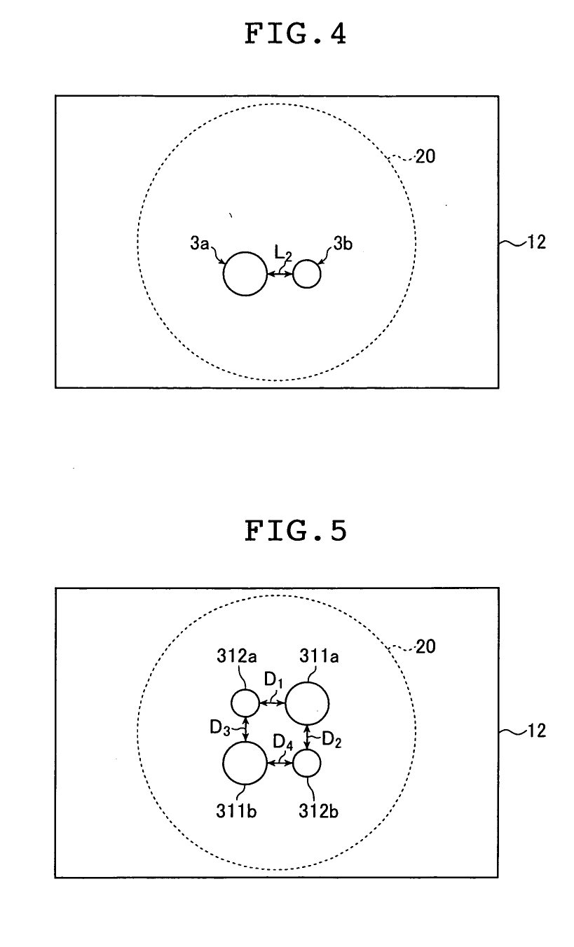

A description is subsequently given of the position relationship among the substrate S, first evaporator, and second evaporator in the vacuum chamber 12 of the vacuum deposition device 10 according to this embodiment. FIG. 2 is a schematic longitudinal sectional view showing the position relationship among the turntable 20, substrate S, Cs evaporator 31a as the first evaporator, and Eu evaporator 31b as the second evaporator in the vacuum chamber 12 of the device 10 of this embodiment. FIG. 3A is a schematic plan view showing the position relationship between the first evaporator and the second evaporator in this embodiment. FIG. 3B is a schematic side view showing the position relationship between the evaporators and the substrate S in this embodiment. FIG. 4 is a plan view of the inside of the vacuum chamber 12 when seen from the turntable 20 side. For the convenience of explanation, a top wall 12a of the vacuum chamber 12, the turntable 20, and the substrate S are omitted from FIG. 3A and FIG. 4.

As shown in FIG. 1 and FIG. 2, the evaporating unit 31, that is, the Cs evaporator 31a and the Eu evaporator 31b are installed in the lower part of the vacuum chamber 12, and the turntable 20 is installed in the upper part of the vacuum chamber 12. The substrate S is held in the lower surface side of the turntable 20 in FIG. 1.

In the vacuum deposition device 10 of this embodiment, the distance L₁ in the vertical direction between the evaporating unit 31 (that is, one of the evaporation port of the Cs evaporator 31a and the evaporation port of the Eu evaporator 31b closer to the substrate S than the other) and the substrate S is 100 to 300 nm. When the distance L₁ in the vertical direction between the evaporating unit 31 and the substrate S is smaller than 100 mm, it is difficult to form a uniform phosphor film on the surface of the substrate S. When the distance L₁ in the vertical direction between the evaporating unit 31 and the substrate S is larger than 300 mm, film forming material particles evaporated from the evaporating unit 31 are blocked by molecules such as argon molecules existent in the vacuum chamber and cannot reach the surface of the substrate S under so-called “medium vacuum” where a high-quality phosphor film is obtained, thereby making it impossible to deposit a film. In addition, the distance L₁ in the vertical direction between the evaporating unit 31 and the substrate S is preferably 100 to 200 mm.

As shown in FIG. 2, the evaporating unit 31 (the Cs evaporator 31a and the Eu evaporator 31b) is installed below the substrate S held by the turntable 20 in the vacuum deposition device 10. The substrate S and the Cs evaporator 31a/the Eu evaporator 31b are spaced apart from each other by a distance L₂ which satisfies the following expression (1).
0.3≦L₁/L₂≦50 (1)

In the expression (1), L₁ is the distance in the vertical direction between the horizontal plane of the evaporation port of each evaporator of the evaporating unit 31, that is, the horizontal plane passing the evaporation port of each evaporator of the evaporating unit 31 and the surface of the substrate S (see FIG. 3B). When the evaporation port of the first evaporator and the evaporation port of the second evaporator differ from each other in height, the distance in the vertical direction between one of the evaporation port of the first evaporator and the evaporation port of the second evaporator closer to the substrate S than the other, and the surface of the substrate S is taken as L₁.

For example, in the embodiment of FIG. 2, when the evaporation port 3a of the Cs evaporator 31a as the first evaporator and the evaporation port 3b of the Eu evaporator 31b as the second evaporator differ from each other in height, the distance in the vertical direction between one of the evaporation port 3a and the evaporation port 3b closer to the substrate S than the other, and the surface of the substrate S becomes L₁.

In the expression (1), L₂ is the shortest distance between the evaporation port 3a of the Cs evaporator 31a as the first evaporator and the evaporation port 3b of the Eu evaporator 31b as the second evaporator. The distance between the evaporation ports is defined as the shortest distance when the ends of the ports are connected to each other as shown in FIG. 3A and FIG. 4. Since there are only one first evaporator (Cs evaporator 31a) and only one second evaporator (Eu evaporator 31b) in this embodiment, the first evaporator and the second evaporator at a position where they are closest to each other are the Cs evaporator 31a and the Eu evaporator 31b, respectively. As will be described hereinafter, when there are plural first evaporators and plural second evaporators, the distance between an evaporation port of a first evaporator and an evaporation port of a second evaporator at positions where the evaporators are closest to each other is L₂.

The value of L₁/L₂ in the above expression (1) has been set in the range of 0.3 to 50. When L₁/L₂ is smaller than 0.3, the degree of design freedom lowers. For instance, the shutters (not shown) for opening and closing the evaporation ports 3a and 3b, which are provided at the evaporation port 3a of the first evaporator (Cs evaporator 31a ) and the evaporation port 3b of the second evaporator (Cs evaporator 31b), cannot be mechanically mounted. Further, the distance between the evaporation port 3a of the first evaporator and the evaporation port 3b of the second evaporator becomes relatively large and a uniform europium distribution in the deposited film cannot be obtained.

When L₁/L₂ is larger than 50, as the distance that the film forming materials can reach from the evaporators is short under so-called “medium vacuum”, the film forming materials cannot reach the surface of the substrate S and a deposited film cannot be obtained. When the distance between the first evaporator and the second evaporator is too short, heat generated from an evaporator and heat from the other evaporator affect each other, thereby making it difficult to control the temperature of each evaporator and deteriorating the deposited film. L₁/L₂ preferably satisfies 1≦L₁/L₂≦50 and more preferably 1≦L₁/L₂≦20.

The distance L₂ between the first evaporator and the second evaporator is preferably 10 to 150 mm, more preferably 10 to 100 mm. When the distance L₂ between the first evaporator and the second evaporator is too short, the degree of design freedom lowers. For example, the shutter for opening and closing the evaporation port of the first evaporator and the shutter for opening and closing the evaporation port of the second evaporator may not be mechanically mounted. Further, heat generated from an evaporator and heat from the other evaporator affect each other, which may cause difficulty in controlling the temperature of each evaporator and deterioration of the deposited film. When the distance L₂ between the first evaporator and the second evaporator is too large, a uniform europium distribution in the deposited film may not be obtained.

The number of revolution R₁ of the turntable 20 is preferably 1 to 20 rpm. When the number of revolution R, of the turntable 20 is too low, a film having a uniform composition may not be deposited and when the R₁ of the turntable 20 is too high, it may be difficult to form a crystal having a columnar structure in the deposited film. The turntable 20 rotates on its axis and also may revolve around. The expression “revolve around” means that the turntable 20 moves in such a manner that its rotation shaft 18 draws a circular locus on a plane parallel to the top wall 12a of the vacuum chamber 12.

In the above embodiment, one first evaporator (Cs evaporator 31a) and one second evaporator (Eu evaporator 31b) are provided in the lower part of the vacuum chamber 12. However, the present invention is not limited to this. Two or more first evaporators (Cs evaporators 31a) and two or more second evaporators (Eu evaporators 31b) may be provided. For example, the evaporators may be installed at positions shown in FIGS. 5 to 7. FIGS. 5 to 7 are plan views in which the top of the vacuum deposition device according to Modifications (1 to 3) of the present invention is omitted, showing the arrangement of first evaporators (Cs evaporators 311a, 311b, 311c, 311d) and the second evaporators (Eu evaporators 312a, 312b, 312c, 312d).

(Modification 1)

FIG. 5 is a plan view showing the arrangement of first evaporators and second evaporators according to Modification 1. In Modification 1, two first evaporators (Cs evaporators 311a and 311b) and two second evaporators (Eu evaporators 312a and 312b) are provided, and the four evaporators are arranged below the turntable 20 shown by a dotted line in FIG. 5 and form a rectangle. In this Modification 1, the four evaporators 311a, 311b, 312a, and 312b are installed on four points forming the rectangle. Therefore, of the distance D₁ between the evaporation port of the Cs evaporator 311a and the evaporation port of the Eu evaporator 312a, the distance D₂ between the evaporation port of the Cs evaporator 311a and the evaporation port of the Eu evaporator 312b, the distance D₃ between the evaporation port of the Cs evaporator 311b and the evaporation port of the Eu evaporator 312a, and the distance D₄ between the evaporation port of the Cs evaporator 311b and the evaporation port of the Eu evaporator 312b, the shortest distance becomes L₂ in the expression (1).

(Modification 2)

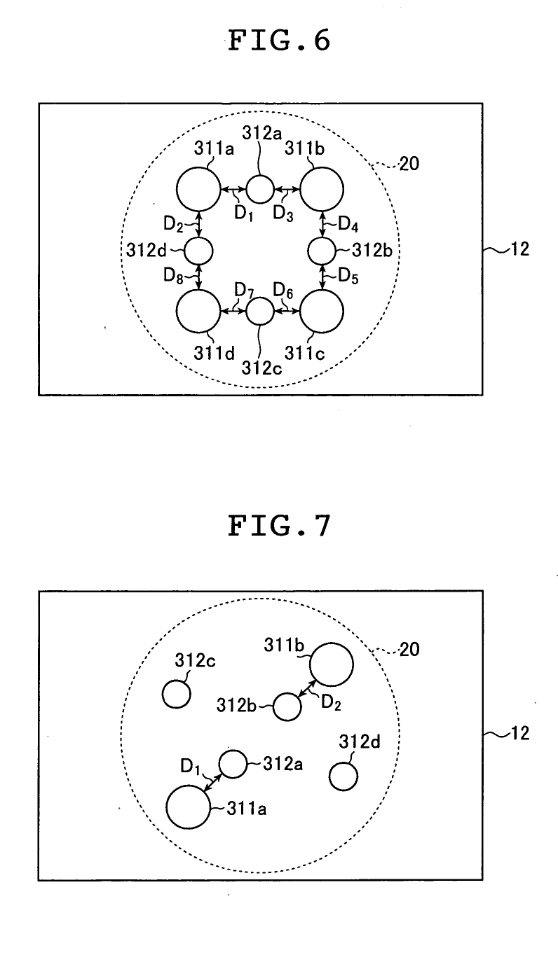

FIG. 6 is a plan view showing the arrangement of first evaporators and second evaporators according to Modification 2. In this Modification 2, four first evaporators (Cs evaporators 311a, 311b, 311c, 311d) and four second evaporators (Eu evaporators 312a, 312b, 312c, 312d) are provided, and the eight evaporators are arranged below the turntable 20 shown by a dot line in FIG. 6 and form a rectangle. In this Modification 2, the Cs evaporators 311a, 311b, 311c, and 311d as the four first evaporators are installed on four points forming the rectangle and the Eu evaporators 312a, 312b, 312c, and 312d as the second evaporators are installed on the respective sides of the rectangle. Therefore, of the distance D₁ between the evaporation port of the Cs evaporator 311a and the evaporation port of the Eu evaporator 312a, the distance D₂ between the evaporation port of the Cs evaporator 311a and the evaporation port of the Eu evaporator 312d, the distance D₃ between the evaporation port of the Cs evaporator 311b and the evaporation port of the Eu evaporator 312a, the distance D₄ between the evaporation port of the Cs evaporator 311b and the evaporation port of the Eu evaporator 312b, the distance D₅ between the evaporation port of the Cs evaporator 311c and the evaporation port of the Eu evaporator 312b, the distance D₆ between the evaporation port of the Cs evaporator 311c and the evaporation port of the Eu evaporator 312c, the distance D₇ between the evaporation port of the Cs evaporator 311d and the evaporation port of the Eu evaporator 312c, and the distance D₈ between the evaporation port of the Cs evaporator 311d and the evaporation port of the Eu evaporator 312d, the shortest distance becomes L₂ in the expression (1).

(Modification 3)

FIG. 7 is a plan view showing the arrangement of first evaporators and second evaporators according to Modification 3.

In this Modification 3, two first evaporators (Cs evaporators 311a, 311b) and four second evaporators (Eu evaporators 312a, 312b, 312c, 312d) are provided, and the six evaporators are arranged below the turntable 20 shown by a dotted line in FIG. 7. In this modification, as shown in FIG. 7, the Cs evaporator 311a is closer to the Eu evaporator 312a, and the CS evaporator 311b is closer to the Eu evaporator 312b. Therefore, of the distance DI between the evaporation port of the Cs evaporator 311a and the evaporation port of the Eu evaporator 312a and the distance D₂ between the evaporation port of the Cs evaporator 311b and the evaporation port of the Eu evaporator 312b, the shortest distance becomes L₂ in the expression (1).

The method of forming a phosphor film in the device 10 according to the first embodiment of the present invention is described below in further detail.

As described above, the device 10 according to this embodiment carries out two-source vacuum deposition by introducing gas and performing resistance heating. To manufacture a phosphor sheet, the substrate S is first mounted on the undersurface of the turntable 20 at a predetermined position with the film forming surface facing down, the vacuum chamber 12 is closed to reduce the internal pressure, and the substrate S is heated from its rear surface with a sheathed heater 24.

An inert gas such as Ar gas is introduced into the vacuum chamber 12 to reduce the internal pressure of the vacuum deposition device 10 to a predetermined degree of vacuum (preferably about 0.05 to 10 Pa, more preferably about 0.5 to 1.5 Pa). After the internal pressure of the vacuum chamber 12 reaches a predetermined degree of vacuum, the turntable 20 is turned at a predetermined speed with a rotation drive source 18. That is, the formation of a phosphor film is started in the heating evaporating section 16 while the substrate S is turned at a predetermined speed.

Stated more specifically, in the heating evaporating section 16, the resistance heater 34 of the Eu evaporator 31b is driven to evaporate europium bromide (EuBr₂) in the evaporation position (crucible), and the resistance heater 36 of the Cs evaporator 31a is driven to evaporate cesium bromide (CsBr) in the evaporation position in the same way to thereby start the deposition of CsBr:Eu on the substrate S, that is, the formation of a phosphor film of interest.

In the case of deposition by resistance heating, a current is applied to the resistance heater to heat the evaporation source. The main component, activator component, and the like of the stimulable phosphor as the evaporation sources are evaporated and diffused by heating. A reaction between both the components occurs to form a phosphor which is then deposited on the surface of the substrate. When deposition is carried out by introducing an inert gas as in this embodiment, use of the resistance heater is preferred.

The Eu evaporator 31b and the Cs evaporator 31a are spaced apart from each other by the distance L₂ as described above and arranged close to each other. Thus, a mixed vapor of film forming materials containing a vapor of an extremely trace amount of europium bromide (EuBr₂) dispersed therein uniformly is formed near the heating evaporating section 16. In addition, CsBr:Eu containing the activator dispersed therein uniformly is deposited with this mixed vapor.

After the formation of a film having a predetermined thickness is over, the revolution of the turntable 20 is stopped, and the vacuum state of the vacuum chamber 12 is released to take out the substrate S on which the phosphor film has been formed. To carry out film formation continuously, after a new substrate S is set likewise, film formation may be carried out.

According to the vacuum deposition device 10 of the above embodiment, the substrate S, CS evaporator 31a, and Eu evaporator 31b are installed at suitable positions and the number of revolution of the turntable 20 is set at a suitable value. Therefore, the thickness of the phosphor film can be controlled accurately and a high-quality phosphor sheet having uniform and favorable X-ray characteristics can be manufactured.

In the above embodiment, the substrate is turned relative to the evaporators. The present invention is not limited to this. The present invention can be applied to various methods in which substrate is moved relative to the evaporators. For instance, the substrate may be moved linearly relative to the evaporators, which will be described later. Alternatively, the substrate may be moved in a zigzag manner including linear and vertical movements.

The following examples are given to further illustrate the present invention.

### EXAMPLES

Two-source vacuum deposition was carried out. That is, as shown in FIG. 1, FIG. 2, and FIG. 4, two evaporators (Cs evaporator 31a and Eu evaporator 31b) of the evaporating unit 31 were used. The conditions for evaporating film forming materials were fixed, and the height of the substrate S, and the position of the Cs evaporator 31a and the position of the Eu evaporator 31b were changed to compare the formed phosphor films in terms of Eu distribution (ratio of the number of Eu atoms to the number of Cs atoms) and image nonuniformity {structure ((PSL), columnarity)} (Experiment 1). Experiment 1 was conducted without turning the substrate. Further, variations in the thickness of a phosphor film and the columnarity of the phosphor crystal of the phosphor film were compared when the number of revolution R₁ of the substrate S was changed (Experiment 2).

Film Forming Materials:

Cesium bromide (CsBr) powder having a purity of 4N or more was prepared as a first film forming material and a CS evaporator as a first evaporator containing this material was prepared. Europium bromide (EuBr₂) powder having a purity of 3N or more was prepared as a second film forming material and an Eu evaporator as a second evaporator containing this material was prepared. When trace elements in the first film forming material (cesium bromide (CsBr) powder) and the second film forming material (europium bromide (EuBr₂) powder) were analyzed by means of ICP-MS (inductively coupled plasma spectrometry-mass spectrometry), the amounts of alkali metals (Li, Na, K, Rb) other than Cs in CsBr were each 10 ppm or less and the amounts of other elements such as alkali earth metals (Mg, Ca, Sr, Ba) were each 2 ppm or less. The amounts of rare earth elements other than Eu in EuBr₂ were each 20 ppm or less and the amounts of other elements were each 10 ppm or less.

Arrangement of Evaporators:

As shown in FIG. 1 and FIG. 2, the Cs evaporator (31a) and the Eu evaporator (31b) were installed below the turntable 20 in the vacuum chamber 12.

The distance L₁ in the vertical direction between the Cs evaporator (31a)/the Eu evaporator (31b) and the substrate S was changed to 120 mm (Comparative Example 1, Examples 1 to 4, 8 to 10 and 14) and to 170 mm (Comparative Example 2, Examples 5 to 7, 11 to 13 and 15).

The shortest distance L₂ between the evaporation port 3a of the Cs evaporator (31a) and the evaporation port 3b of the Eu evaporator (31b) was changed to 4 mm (Example 4 and Example 7), 10 mm (Example 3 and Example 6), 100 mm (Example 2), 400 mm (Example 1), 420 mm (Comparative Example 1), 500 mm (Example 5), and 600 mm (Comparative Example 2). In Experiment 2, the value of L₂ was 10 mm.

With regard to L₁/L₂ (ratio of the distance L, in the vertical direction between one of the Cs evaporator (31a) and the Eu evaporator (31b) closer to the substrate S than the other, and the substrate S, to the shortest distance L₂ between the evaporation port 3a of the Cs evaporator (31a) and the evaporation port 3b of the Eu evaporator (31b)) in Experiment 1, as shown in Table 1, the ratio in Examples 1 to 7 was within the range of 0.3 to 50 which is the condition of the expression (1) of the present invention, whereas the ratio in Comparative Examples 1 and 2 was less than 0.3. In Experiment 2, as shown in Table 2, L₁/L₂ fell in all cases within the range of 0.3 to 50 which is the condition of the expression (1) of the present invention.

Formation of Phosphor Film:

A substrate S composed of synthetic quartz which had been cleaned with an alkali, pure water, and IPA (isopropyl alcohol) in this order was prepared as a support and set on a substrate S holder in the vacuum deposition device 10. CsBr as the first film forming material and EuBr₂ as the second film forming material were filled into the Cs evaporator 31a and the Eu evaporator 31b in the above embodiment and the internal pressure of the vacuum chamber 12 was set at 1×10⁻³ Pa. After that, Ar gas was introduced into the vacuum chamber 12 to reduce the degree of vacuum to 1.0 Pa. Then, the substrate S was heated to 100° C. with the sheathed heater 24 to carry out deposition. The distance in the vertical direction between the substrate S and the first evaporator/the second evaporator was maintained at 120 mm (or 170 mm) to deposit a CsBr:Eu stimulable phosphor on the substrate S at a rate of 5 μm/minute. By controlling a current to the heaters, the molar ratio of Eu to Cs in the stimulable phosphor was adjusted to 0.003/1.

The phosphor films formed as described above were compared with one another in terms of Eu distribution and structure (PSL, columnarity) (Experiment 1). Further, variations in the thickness of the phosphor film and the columnarity of the phosphor crystal of the phosphor film when the number of revolution R₁ (number of rotation on its axis) of the substrate S was changed were compared

(Experiment 2).

(Measurement Method)

(Experiment 1)

(1) Eu Distribution

This was measured by means of ICP-MS. The measurement positions were a position above the Cs evaporator in the vacuum chamber 12 (to be referred to as “above Cs”, the same shall apply to Table 1), a position 30 mm in a direction away from the Eu evaporator from above the Cs evaporator (to be referred to as “above Cs−30 mm”, the same shall apply to Table 1), and a position 30 mm in a direction toward the Eu evaporator from above the Cs evaporator (to be referred to as “above Cs+30 mm”, the same shall apply to Table 1). The Eu distribution was shown specifically in terms of the ratio ([Eu]/[Cs]) of the number of Eu atoms to the number of Cs atoms in the formed phosphor film.

(2) PSL (Intensity of Photostimulated Luminescence)

PSL was measured as follows. The obtained panel was set in a cassette capable of shielding against room light, a lead plate was placed on this radiation image converting panel, and 100 mR of X-rays having a tube voltage of 80 kVp was applied to the lead plate. After the panel had been taken out from the cassette, the panel was excited with LD laser light (wavelength: 650 nm) and light emitted from the panel upon stimulation was detected with a photomultiplier to obtain the amount of the light. The positions measured for PSL were a position above the CS evaporator (above Cs) in the vacuum chamber 12, a position 30 mm in a direction away from the Eu evaporator from above the CS evaporator (above Cs−30 mm), and a position 30 mm in a direction toward the Eu evaporator from above the Cs evaporator (above Cs+30 mm).

(3) (Columnarity)

Columnarity was measured as follows. The phosphor layer of the radiation image converting panel was cut in a thickness direction together with the support and coated with gold (thickness: 300 Å) by means of ion sputtering to prevent charge-up. Then, the surface and cut section of the phosphor layer were observed through a scanning electron microscope (JSM-5400 of JEOL Ltd.) to evaluate the shape of a columnar crystal based on the following criteria. The measurement of columnarity was carried out above the Cs evaporator (above Cs) in the vacuum chamber 12. The measurement of Experiment 1 was conducted under the following conditions. The results are shown in Table 1.

TABLE 1

| | | | | Eu distribution (ratio | | | | | | | |
|---|---|---|---|---|---|---|---|---|---|---|---|
| | | | | of number of Eu atoms | | | PSL (after correction of film | | | | |
| | | | | to number of Cs atoms) | | | thickness) | | | | |
| | | | | above | above | above | above | above | above | | Columnarity |
| | L₁ | L₂ | L₁/L₂ | Cs − 30 mm | Cs | Cs + 30 mm | Cs − 30 mm | Cs | Cs + 30 mm | Uniformity | (above Cs) |
| Comparative | 120 | 420 | 0.28 | 6.90E−04 | 2.0E−3 | 8.00E−03 | 66 | 100 | 71 | X | ⊚ |
| Example 1 | | | | | | | | | | | |
| Comparative | 170 | 600 | 0.28 | 6.70E−04 | 2.0E−3 | 7.80E−03 | 63 | 100 | 72 | X | ⊚ |
| Example 2 | | | | | | | | | | | |
| Example 1 | 120 | 400 | 0.30 | 8.50E−04 | 2.0E−3 | 6.30E−03 | 80 | 100 | 93 | ◯ | ⊚ |
| Example 2 | 120 | 100 | 1.20 | 1.10E−03 | 2.0E−3 | 5.00E−03 | 97 | 100 | 95 | ⊚ | ⊚ |
| Example 3 | 120 | 10 | 12.00 | 1.30E−03 | 2.0E−3 | 3.10E−03 | 98 | 100 | 98 | ⊚ | ⊚ |
| Example 4 | 120 | 4 | 30.00 | 1.40E−03 | 2.0E−3 | 2.50E−03 | 99 | 100 | 100 | ⊚ | ⊚ |
| Example 5 | 170 | 500 | 0.34 | 8.60E−04 | 2.0E−3 | 5.90E−03 | 83 | 100 | 93 | ◯ | ⊚ |
| Example 6 | 170 | 10 | 17.00 | 1.50E−03 | 2.0E−3 | 2.80E−03 | 100 | 100 | 99 | ⊚ | ⊚ |
| Example 7 | 170 | 4 | 42.50 | 1.70E−03 | 2.0E−3 | 2.20E−03 | 100 | 100 | 100 | ⊚ | ⊚ |

In the results of individual items in Table 1 and Table 2 to be described hereinafter, the symbol “X” means that the shape of the columnar crystal is bad and has a problem in practical use, “Δ” means that the shape is at a usable level, “◯” means that the shape is satisfactory, and “\mathring{◯}” means that the shape is excellent.

The expression “correction of film thickness” in PSL (after correction of film thickness) in Table 1 means a PSL relative value in terms of unit film thickness when the PSL value “above Cs” is 100 and the film thickness “above Cs” is unit film thickness.

(Eu Distribution (Ratio of Number of Eu Atoms to Number of Cs Atoms)

As the results of Table 1 show, in Comparative Example 1, the value measured at the position (above Cs) was 2.0×10⁻³, the value measured at the position (above Cs−30 mm) was 6.90×10⁻⁴ which is about ⅓ the value measured at the position (above Cs), and the value measured at the position (above Cs+30 mm) was 8.00×10⁻³ which is about 4 times as large as the value measured at the position (above Cs). Similarly, in Comparative Example 2, the value measured at the position (above Cs) was 2.0×10⁻³, the value measured at the position (above Cs−30 mm) was 6.70×10⁻⁴ which is about ⅓ the value measured at the position (above Cs), and the value measured at the position (above Cs+30 mm) was 7.80×10⁻³ which is about 4 times as large as the value measured at the position (above Cs).

Meanwhile, in Examples 1 to 7, the value measured at the position (above Cs) was 2.0×10⁻³, the value measured at the position (above Cs−30 mm) was 8.50×10⁻⁴ to 1.70×10⁻³, and the value measured at the position (above Cs+30 mm) was 3.10×10⁻³ to 6.30×10⁻³. There are smaller differences in measurement value among the measurement positions than those of Comparative Examples 1 and 2. The results show that Eu atoms are uniformly distributed as compared with Comparative Examples 1 and 2.

When Examples 1 to 4 in which the L₁ value is 120 mm are compared with one another, as for the values measured at the position (above Cs−30 mm) and the values measured at the position (above Cs+30 mm), as the L₂ value becomes smaller, the ratio of the number of Eu atoms to the number of Cs atoms becomes lower. The lower ratio means that variations in Eu atoms tend to become smaller. This tendency is also seen in Examples 5 to 7 in which the L₁ value is 170 mm.

(PSL)

As the results of Table 1 show, in Comparative Example 1, the value measured at the position (above Cs) was 100, the value measured at the position (above Cs−30 mm) was 66, and the value measured at the position (above Cs+30 mm) was 71. Similarly, in Comparative Example 2, the value measured at the position (above Cs) was 100, the value measured at the position (above Cs−30 mm) was 63, and the value measured at the position (above Cs+30 mm) was 72.

Meanwhile, in Examples 1 to 7, the value measured at the position (above Cs) was 100, the value measured at the position (above Cs−30 mm) was 80 to 100, and the value measured at the position (above Cs+30 mm) was 93 to 100. The differences in measurement value among the measurement positions are smaller than those of Comparative Examples 1 and 2. The results show that the composition is more uniform than those in Comparative Examples 1 and 2.

When Examples 1 to 4 in which the L₁ value is 120 mm are compared with one another, as for the values measured at the position (above Cs−30 mm) and the values measured at the position (above Cs+30 mm), as the L₂ value becomes smaller, the PSL value becomes smaller. The lower PSL value means that variations in film composition tend to become small. This tendency is also seen in Examples 5 to 7 in which the L₁ value is 170 mm.

(Columnarity)

No significant difference in columnarity was seen between Comparative Examples 1 and 2 and Examples 1 to 7.

(Experiment 2)

(4) Film Thickness

The thickness of each film was measured with a stylus profilometer.

(5) Columnarity

Columnarity was measured in the same manner as in (3) above. The measurements of Experiment 2 were made under the above conditions. The results are shown in Table 2.

TABLE 2

| | | | | Number of | | |
|---|---|---|---|---|---|---|
| | | | | revolution | Variation | |
| | | | | of substrate | in film | |
| | L₁ | L₂ | L₁/L₂ | R₁ (rpm) | thickness | Columnarity |
| Example 8 | 120 | 10 | 12.00 | 0 | Δ | Δ |
| Example 9 | 120 | 10 | 12.00 | 0.5 | ◯ | Δ |
| Example 10 | 120 | 10 | 12.00 | 50 | ⊚ | Δ |
| Example 11 | 170 | 10 | 17.00 | 0 | Δ | Δ |
| Example 12 | 170 | 10 | 17.00 | 0.5 | ◯ | Δ |
| Example 13 | 170 | 10 | 17.00 | 50 | ⊚ | Δ |
| Example 14 | 120 | 10 | 12.00 | 20 | ⊚ | ⊚ |
| Example 15 | 170 | 10 | 17.00 | 20 | ⊚ | ⊚ |

(Columnarity)

As the results of Table 2 show, a phosphor film is obtained at a usable level even when the substrate is not turned. As also seen from Examples 9, 10 and 12 to 15, the variations in film thickness are reduced by turning the substrate, and excellent results are obtained particularly in Examples 14 and 15 in which the number of revolution R1 is 20 rpm. It can be thus seen that an excellent phosphor film having smaller variations in film thickness is obtained by moving the substrate relative to the evaporation sources.

(Variation in Film Thickness)

When attention is paid to variations in film thickness, as the number of revolution R₁ is raised from 0 rpm to 0.5 rpm and 50 rpm, variations in film thickness are reduced. This result shows that variations in film thickness become smaller by turning the turntable 20 and as the number of revolution R₁ becomes higher, variations in film thickness become smaller.

The vacuum deposition method and the vacuum deposition device according to the present invention have been described above referring to a substrate rotation type vacuum deposition device. A case where the vacuum deposition method of the present invention is implemented using a device in which vacuum deposition is carried out by linearly transporting the substrate S will now be described.

FIG. 8 shows a schematic constitution of a vacuum deposition device 100 in which vacuum deposition is carried out by linearly transporting the substrate S. The vacuum deposition device 110 has basically the same constitution as the vacuum deposition device 10 shown in FIG. 1 except that the substrate holding and rotating mechanism 14 for holding the substrate S in the vacuum device 10 shown in FIG. 1 is replaced by a substrate holding and transporting mechanism 114 for holding and linearly transporting the substrate in the vacuum deposition device 110 and that plural evaporators are arranged in a direction parallel to the substrate surface and perpendicular to the substrate transport direction.

The substrate holding and transporting mechanism 114 can be composed of substrate holding unit (substrate holding means) for holding the substrate and linear transport unit (linear transport means) for linearly moving the substrate holding unit. In FIG. 8, the linear transport unit is composed of a ball screw 84. By rotating a screw shaft 84a of the ball screw 84 by a motor 86, the substrate holding unit 82 fixed to a nut portion 84b of the ball screw 84 is linearly transported while being guided by a guide rail. The ball screw 84 is used as the linear transport unit in this embodiment, but this is not the sole case of the present invention. A linear transport device using a linear motor, a transport device using a cylinder, a rack-and-pinion type transport device, and a transport device rotated by a motor and using a ring-shaped chain can be used.

In the transport of the substrate S by the substrate holding and transporting mechanism 114, linear to-and-fro motion of the substrate is repeated several times to form a phosphor film having a uniform and sufficiently large film thickness. However, the method for the transport of the substrate is not limited to this and the substrate may be moved only in one direction if a desired film is obtained.

The transport speed of the substrate is preferably 1 to 1000 mm/sec and more preferably 20 to 300 mm/sec in order to form a film having a uniform film thickness on the substrate.

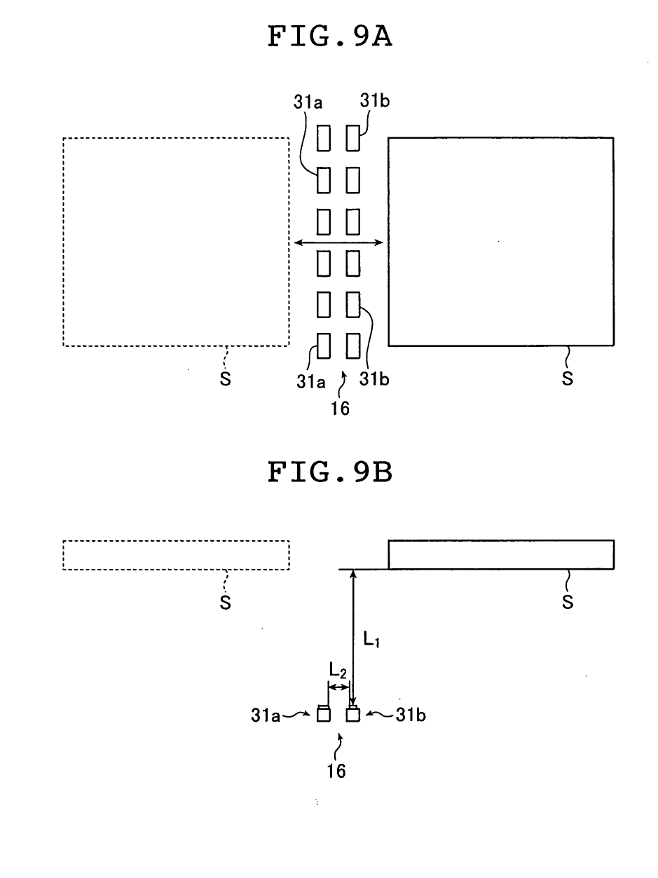

The arrangement of each evaporator of the evaporating unit 31 in the case where the substrate S is linearly transported as described above will be described below with reference to FIGS. 9A and 9B. Although the evaporators of the vacuum deposition device shown in FIG. 1 were in a cylinder shape, the evaporators in the vacuum deposition device shown in FIG. 8 are in a rectangular solid shape and, for the sake of convenience, two types of evaporators are shown by the same size. There are no particular limitations on the size and shape of the evaporators and the size and the shape can be appropriately changed depending on the film forming materials used and the composition of the film to be formed on the substrate. In this embodiment, plural evaporators (Cs evaporators 31a and Eu evaporators 31b) (in the illustrated case, six evaporators for each type) are arranged in a direction perpendicular to the transport direction of the substrate S. A phosphor film having a more uniform film thickness can be thus formed by arranging the evaporating unit 31 in a direction perpendicular to the substrate transport direction and by carrying out vacuum deposition while transporting the substrate S in a to-and-fro manner.

In the embodiment shown in FIGS. 9A and 9B, one line is formed for each of the Cs evaporators 31a and the Eu evaporators 31b. However, the present invention is not limited to this. One line may be formed for the Eu evaporators 31b whose deposition amount is small and two lines for the Cs evaporators 31a. Alternatively, more than one line may be formed for both the evaporators 31a and 31b. In the last case, the number of lines for the Cs and Eu evaporators 31a and 31b may be the same or different. In addition, the height of the evaporators may be changed for each line depending on the amount of the evaporation flow generated from the evaporators. To be more specific, when the vapor from one type of the evaporators is to be deposited on the substrate in a smaller amount than the vapor from the other type of the evaporators, the amount of the vapor generated from the former type must be made smaller than that from the latter type. In this practice, the evaporation flow generated from the latter type of the evaporators interferes with the evaporation flow which was generated from the former type of the evaporators and whose amount is small, which may result in insufficient mixture and poor distribution. In this case, the evaporation ports of the evaporators from which the evaporation amount is to be decreased are preferably positioned above the evaporation ports of the other type of the evaporators and hence closer to the substrate to adjust the evaporation flow to be more powerful. In both the cases, the substrate S and the evaporators 31a, 31b are arranged so as to satisfy the expression (1).

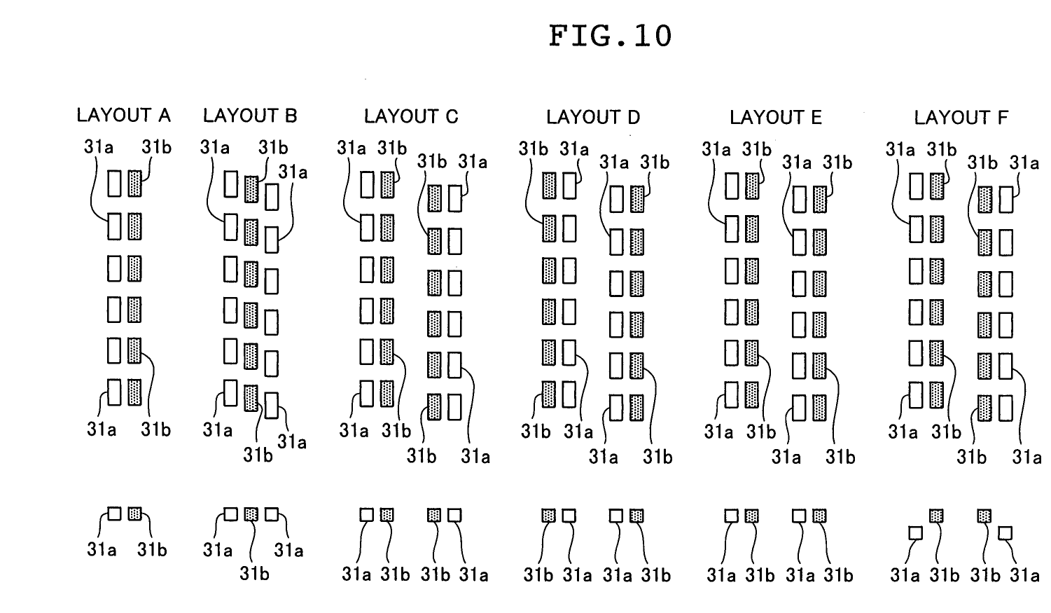

FIG. 10 shows exemplary layouts of the evaporators in the vacuum deposition device. The evaporating unit 31 is seen from the above in the upper side view and from the front side in the lower side view. The horizontal direction in FIG. 10 is the substrate transport direction.

In FIG. 10, the layout A shows the arrangement of the evaporators shown in FIG. 9A, that is, two lines of the evaporators are arranged in this layout. The layout B shows the arrangement of three lines of the evaporators. In the layout B, one line of the Cs evaporators 31a are arranged on both side of the line of the Eu evaporators 31b, and the arranged three lines of the evaporators are shifted in a direction parallel to the substrate surface and perpendicular to the transport direction (hereinafter simply referred to as the direction perpendicular to the transport direction) sequentially from the left side to the right side in FIG. 10. In other words, evaporators of the respective lines are arranged so that a space between adjacent two evaporators in the line direction is partially blocked by one evaporator in the next line of the evaporators. This arrangement allows a phosphor sheet having a more uniform film thickness in the direction in which the evaporation sources are arranged to be formed. Further, the evaporators in the respective lines are arranged so that the distance between the right line and the central line is the same as that between the central line and the left line.

The layout C shows the arrangement of four lines of the evaporators and in this arrangement, two lines of the Eu evaporators 31b are arranged inside and the lines of the Cs evaporators 31a are arranged on both the outer sides, respectively. The respective two lines of the evaporators on the left side in FIG. 10 are arranged with their positions in the direction perpendicular to the transport direction coinciding with each other. The two lines of the evaporators in the right side in FIG. 10 have also the same arrangement as the above. The left two lines of the evaporators in FIG. 10 are shifted from the right two lines of the evaporators in the direction perpendicular to the transport direction. The four lines of the evaporators are arranged so that the distance between the inside two lines of the evaporators is larger than that between the right or left side two lines of the evaporators.

The layout D shows the arrangement in which the Cs evaporators 31a and the Eu evaporators 31b in the layout C are reversed. The layout E shows the arrangement in which the right side two lines of the evaporators (Cs evaporators 31a and Eu evaporators 31b) in the layout C are reversed.

The layout F shows the arrangement in which the planar arrangement is the same as that of the layout C, but the Cs evaporators 31a are different from the Eu evaporators 31b in height in the direction perpendicular to the substrate surface (height direction). In this layout, the Cs evaporators 31a are lower than the Eu evaporators 31b. When the Cs evaporators 31a are different from the Eu evaporators 31b in height as described above, L₂ denotes the horizontal distance between the evaporation ports of the Cs evaporator 31a and the Eu evaporator 31b. In this case, L₁ used in the expression (1) includes the distance L₁ (Cs) between the horizontal plane to which the evaporation port of the Cs evaporator 31a belongs and the surface of the substrate, and the distance L₁ (Eu) between the horizontal plane to which the evaporation port of the Eu evaporator 31b belongs and the surface of the substrate. In this case, the substrate, the Cs evaporators 31a and the Eu evaporators 31b are arranged so that the expression (1) is satisfied irrespective of whether L₁ (Cs) or L₁ (Eu) is used.

Next, 27 types of phosphor films were formed on the substrate under varying film forming conditions by using a linear transport type vacuum deposition device as shown in FIG. 8. More specifically, the layout of the evaporating unit 31 was selected from among the layouts A to F shown in FIG. 10, and L₁/L₂ and the transport speed of the substrate were variously changed to thereby form phosphor sheets on the substrate S. The thus obtained phosphor films (Examples 16 to 35 and Comparative Examples 3 to 9 were evaluated for their Eu concentration distribution, PSL and columnarity in the same method as the above. The results and film forming conditions are shown in Table 3.

TABLE 3

| | | | | | | Eu | | | | |
|---|---|---|---|---|---|---|---|---|---|---|
| | | | | | | CONCENTRATION | | | | |
| | | | | | | DISTRIBUTION | | PSL | | |
| | | | | | TRANSPORT | FILM | FILM | FILM | | |
| | | | | | SPEED | PLANE | THICKNESS | PLANE | COLUMNARITY | |
| | LAYOUT | L₁ | L₂ | L₁/L₂ | mm/sec | DIRECTION | DIRECTION | DIRECTION | COLUMN | DISTRIBUTION |
| EXAMPLE 16 | A | 150 | 70 | 2.14 | 200 | ⊚ | ⊚ | ⊚ | ⊚ | ⊚ |
| EXAMPLE 17 | A | 150 | 300 | 0.50 | 200 | ⊚ | ⊚ | ⊚ | ⊚ | ⊚ |
| EXAMPLE 18 | B | 150 | 70 | 2.14 | 200 | ⊚ | ⊚ | ⊚ | ⊚ | ⊚ |
| EXAMPLE 19 | B | 150 | 300 | 0.50 | 200 | ⊚ | ⊚ | ⊚ | ⊚ | ⊚ |
| EXAMPLE 20 | C | 150 | 70 | 2.14 | 200 | ⊚ | ⊚ | ⊚ | ⊚ | ⊚ |
| EXAMPLE 21 | C | 150 | 20 | 7.50 | 200 | ⊚ | ⊚ | ⊚ | ⊚ | ⊚ |
| EXAMPLE 22 | C | 150 | 300 | 0.50 | 200 | ⊚ | ◯ | ⊚ | ⊚ | ⊚ |
| EXAMPLE 23 | C | 50 | 70 | 0.71 | 200 | ⊚ | ⊚ | ⊚ | ⊚ | ⊚ |
| EXAMPLE 24 | C | 1000 | 70 | 14.29 | 200 | ⊚ | ⊚ | ⊚ | ⊚ | ⊚ |
| EXAMPLE 25 | C | 150 | 70 | 2.14 | 1 | ⊚ | ◯ | ⊚ | ◯ | ⊚ |
| EXAMPLE 26 | C | 150 | 70 | 2.14 | 20 | ⊚ | ◯ | ⊚ | ◯ | ⊚ |
| EXAMPLE 27 | C | 150 | 70 | 2.14 | 1000 | ◯ | ⊚ | ◯ | ⊚ | ⊚ |
| EXAMPLE 28 | D | 150 | 70 | 2.14 | 200 | ⊚ | ⊚ | ⊚ | ⊚ | ⊚ |
| EXAMPLE 29 | D | 150 | 300 | 0.50 | 200 | ⊚ | ⊚ | ⊚ | ⊚ | ⊚ |
| EXAMPLE 30 | E | 150 | 70 | 2.14 | 200 | ⊚ | ⊚ | ⊚ | ⊚ | ⊚ |
| EXAMPLE 31 | E | 150 | 300 | 0.50 | 200 | ⊚ | ⊚ | ⊚ | ⊚ | ⊚ |
| EXAMPLE 32 | F | 150(Cs) | 70 | 2.14 | 200 | ⊚ | ⊚ | ⊚ | ⊚ | ⊚ |
| | | 148(Eu) | | | | | | | | |
| EXAMPLE 33 | F | 150(Cs) | 300 | 0.50 | 200 | ⊚ | ⊚ | ⊚ | ⊚ | ⊚ |
| | | 148(Eu) | | | | | | | | |
| EXAMPLE 34 | C | 150 | 70 | 2.14 | 0.5 | ⊚ | ◯ | ⊚ | ◯ | ⊚ |
| EXAMPLE 35 | C | 150 | 70 | 2.14 | 1500 | ⊚ | ⊚ | ◯ | ◯ | ◯ |
| COMPARATIVE | A | 150 | 600 | 0.25 | 200 | ◯ | X | ◯ | X | ◯ |
| EXAMPLE 3 | | | | | | | | | | |
| COMPARATIVE | B | 150 | 600 | 0.25 | 200 | ◯ | X | ◯ | X | ◯ |
| EXAMPLE 4 | | | | | | | | | | |
| COMPARATIVE | C | 3600 | 70 | 31.43 | 200 | X | X | X | X | X |
| EXAMPLE 5 | | | | | | | | | | |
| COMPARATIVE | C | 150 | 600 | 0.25 | 200 | ◯ | X | ◯ | X | ◯ |
| EXAMPLE 6 | | | | | | | | | | |
| COMPARATIVE | D | 150 | 600 | 0.25 | 200 | ◯ | X | ◯ | X | ◯ |
| EXAMPLE 7 | | | | | | | | | | |
| COMPARATIVE | E | 150 | 600 | 0.25 | 200 | ◯ | X | ◯ | X | ◯ |
| EXAMPLE 8 | | | | | | | | | | |
| COMPARATIVE | F | 150 | 600 | 0.25 | 200 | ◯ | X | ◯ | X | ◯ |
| EXAMPLE 9 | | | | | | | | | | |

As is seen from Table 3, the results of the Eu concentration distribution, PSL and columnarity obtained in all the Examples are excellent. On the other hand, in Comparative Examples 3 to 9, the Eu distribution in the film thickness direction and columnar shape are particularly inferior. This is because, for example, in Comparative Examples 3, 4 and 6 to 9 in which L₁/L₂ is less than 0.3, L₂ (distance between the evaporation ports) is smaller than L₁ (distance between the evaporation port and the substrate), and hence the evaporation flow generated from the evaporation ports of one type of the evaporators becomes larger than that generated from the evaporation ports of the other type of the evaporators depending on the position of the substrate being transported. A columnar structure in which CsBr portions are EuBr₂ portions are alternately stacked on top of each other is formed in the film on the substrate, which impairs the Eu distribution in the film thickness direction. Further, the columnar shape is not stable because of the alternate formation of the CsBr portions and EuBr₂ portions.

As described above in detail, according to the vacuum deposition device and method of the present invention, the substrate, the first evaporator(s), and the second evaporator(s) are installed at predetermined positions, that is, positions which satisfy the above expression (1). Therefore, heat generated from the first evaporator(s) and heat generated from the second evaporator(s) do not affect each other, which allows the temperatures of the first and second evaporators to be controlled separately. As a result, it becomes possible to carry out high-precision temperature control and to manufacture a high-quality phosphor sheet having uniform X-ray characteristics.

1. A vacuum deposition method, comprising the steps of:
evaporating film forming materials from an evaporating unit installed in a vacuum deposition chamber; and
depositing said evaporated film forming materials on a surface of a substrate located above said evaporating unit,
wherein said evaporating unit includes at least one first evaporator for evaporating a first film forming material and at least one second evaporator for evaporating a second film forming material; and
wherein said first and second film forming materials are deposited on the surface of said substrate at a pressure of 0.05 to 10 Pa by installing said substrate, said first evaporator and said second evaporator at positions which satisfy a condition of an expression (1):
0.3≦L₁/L₂≦50 (1)
wherein L₁ is a distance in a vertical direction from a horizontal plane of an evaporation port of said first or second evaporator to the surface of said substrate, and L₂ is the shortest distance between said evaporation port of said first evaporator and said evaporation port of said second evaporator.

2. The vacuum deposition method according to claim 1, wherein said first and second film forming materials are deposited on said substrate while said substrate is turned at a number of revolution R₁ which satisfies 1≦R₁≦20 (rpm) relative to said first and second evaporators.

3. The vacuum deposition method according to claim 1, wherein said first and second film forming materials are deposited on said substrate by linearly transporting said substrate.

4. The vacuum deposition method according to claim 3, wherein said substrate is transported at a transport speed of 1 to 1000 mm/sec.

5. The vacuum deposition method according to claim 3,
wherein first evaporators and second evaporators are used in said evaporating unit, and
wherein a line of said first evaporators and a line of said second evaporators are arranged parallel to each other in a direction parallel to said substrate and perpendicular to a direction in which said substrate is transported, whereby said first and second film forming materials are deposited on said substrate.

6. The vacuum deposition method according to claim 1, wherein said first film forming material comprises CsBr and said second film forming material comprises EuBr₂.

7. A vacuum deposition device, comprising:
a vacuum deposition chamber;
vacuum evacuation means for evacuating inside of said vacuum deposition chamber;
at least one first evaporator which is installed in said vacuum deposition chamber and which evaporates a first film forming material from a first evaporation port;
at least one second evaporator which is installed in said vacuum deposition chamber and which evaporates a second film forming material from a second evaporation port; and
a holding unit for holding a substrate on which said first film forming material and said second film forming material are deposited, said holding unit being provided above said first and second evaporators,
wherein one of said first and second evaporators which is closer to said substrate is spaced apart from said substrate in a vertical direction by 100 to 300 mm; and
wherein said substrate, said first evaporator and said second evaporator are installed at positions which satisfy a condition of an expression (1):
0.3≦L₁/L₂≦50 (1)
wherein L₁ is a distance in a vertical direction from a horizontal plane of said first or second evaporation port of said first or second evaporator to a surface of said substrate, and L₂ is the shortest distance between said first evaporation port of said first evaporator and said second evaporation port of said second evaporator.

8. The vacuum deposition device according to claim 7, wherein the holding unit holds said substrate in such a manner that said substrate turns on a plane opposed to a wall of said vacuum deposition chamber in which said first and second evaporators are installed.

9. The vacuum deposition device according to claim 7, which further includes linear transport means for linearly transporting said substrate by linearly moving said holding unit.

10. The vacuum deposition device according to claim 9,
wherein first evaporators and second evaporators are used in said vacuum deposition chamber and
wherein a line of said first evaporators and a line of said second evaporators are arranged parallel to each other in a direction parallel to said substrate and perpendicular to a direction in which said substrate is transported.

11. The vacuum deposition device according to claim 7, wherein said first film forming material comprises CsBr and said second film forming material comprises EuBr₂.
